(19) United States
(12) Patent Application Publication
(10) Pub. No.: US 2011/0175638 A1
(43) Pub. Date: Jul. 21, 2011

(54) SEMICONDUCTOR INTEGRATED CIRCUIT AND CORE TEST CIRCUIT

(75) Inventor: Toshiyuki MAEDA, Kanagawa (JP)

(73) Assignee: RENESAS ELECTRONICS CORPORATION, Kanagawa (JP)

(21) Appl. No.: 13/007,366

(22) Filed: Jan. 14, 2011

(30) Foreign Application Priority Data
Jan. 20, 2010 (JP) 2010-010376

(51) Int. Cl. G01R 31/26

(52) U.S. Cl. 324/762.01

(57) ABSTRACT

A semiconductor circuit inhibiting the increase in the number of elements required to enable core circuit testing and a core test circuit enabling consecutive-pattern testing of a core circuit without increasing the number of terminals are provided. The semiconductor circuit includes a core circuit, a combinational circuit, a scan path for the combinational circuit with the scan path including cascaded scan flip-flops connected to input and output terminals of the combinational circuit, and scan path sharing circuits including multiplexers for allowing output signals of the core circuit to be inputted to the scan flip-flops, and allows a core circuit not included in the combinational circuit to be tested using the scan path for the combinational circuit. The core test circuit is provided with output shift registers for storing and outputting test results of plural test patterns outputted from output terminals of the core circuit to be eventually scanned out from the output shift registers.

### CROSS-REFERENCE TO RELATED APPLICATIONS

The disclosure of Japanese Patent Application No. 2010-10376 filed on Jan. 20, 2010 including the specification, drawings and abstract is incorporated herein by reference in its entirety.

### BACKGROUND

1. Field of the Invention

The present invention relates to a semiconductor integrated circuit and a core test circuit. More particularly, the invention relates to a semiconductor integrated circuit including a core circuit which may be, for example, a fixed microprocessor, DSP, analog circuit, or memory and a test circuit for testing the core circuit.

2. Description of Related Art

There are semiconductor integrated circuits each including a so-called user logic and a core circuit. A user logic is an unfixed circuit whose function, configuration, and arrangement can be changed according to circuit type. A core circuit has a fixed circuit configuration. For example, microprocessors, DSPs, analog circuits, and memories are among typical core circuits.

Generally, in a semiconductor integrated circuit including a user logic and a core circuit, the core circuit includes an internal test circuit for itself or a core test circuit is provided outside the core circuit, and a separate user logic test circuit is also provided. Such a user logic test circuit is formed by inserting a scan path test circuit in the user logic. A scan path test circuit is inserted in the user logic as follows. First, the user logic is divided into a combinational circuit and a sequential circuit which includes flip-flops to operate in synchronization with clock pulses. The flip-flops are converted into scan flip-flops by making them chain-connectable to one another, and scan chain wiring, not provided for the user logic, is added to the scan flip-flops. There are cases where, with no appropriate flip-flops included in the user logic, scan flip-flops are additionally inserted in the user logic. The total number of scan flip-flops included in a semiconductor integrated circuit with a large-scale user logic ranges from several tens of thousands to over several hundreds of thousands.

In connection with a semiconductor integrated circuit including, as described above, a core circuit and a user logic, a standard method of testing the core circuit is outlined in “IEEE Std. 1500™-2005, IEEE Standard Testability Method for Embedded Core-based Integrated Circuits,” IEEE Computer Society, 7, pp. 11-12 (hereinafter also referred to as the “above non-patent literature”). FIG. 9 is an overall block diagram of a test circuit (wrapper) based on IEEE 1500 Standard shown in FIG. 1 of the above non-patent literature. According to the above non-patent literature, wrapper serial ports (WSPs) for serially controlling test data and test mode, optional wrapper parallel ports (WPPs) for controlling, in parallel, test data and test mode, a wrapper instruction register (WIR) for test mode control, a wrapper bypass register (WBY) used, when performing a test using a serial interface, to bypass the core circuit from the serial chain, and wrapper boundary registers (WBRs) for applying test data, serially or in parallel, to input terminals of the core circuit and for storing and outputting, serially or in parallel, test results outputted from output terminals of the core circuit are provided to enable core circuit testing. The WSPs include a wrapper serial input terminal (WSI) and a wrapper serial output terminal (WSO). The core test circuit (wrapper) must have a serial interface, but a parallel interface is optional.

In Japanese Unexamined Patent Publication No. 2004-320433, it is disclosed that a shift register for use in core testing is provided near an embedded core circuit. It is also disclosed that a scan path circuit of a combinational circuit provided near the embedded core circuit is connected to a rear of the shift register for core testing and that test data is scanned in from the input terminal of the shift register for core testing to be scanned out from the output terminal of the scan path circuit.

### SUMMARY

According to the above non-patent literature or Japanese Unexamined Patent Publication No. 2004-320433, a semiconductor integrated circuit including a core circuit and a combinational circuit other than the core circuit is required to have a register specialized to hold test patterns to be applied to the core circuit and a register specialized to hold test results (such as the WBRs described in the above non-patent literature and the shift register 13 for core testing described in Japanese Unexamined Patent Publication No. 2004-320433). This increases the test circuit overhead.

In cases where a core circuit is tested using WSPs as described in the above non-patent literature or where, as described in Japanese Unexamined Patent Publication No. 2004-320433, test patterns serially scanned in are used to test a core circuit and test results are subsequently scanned out, every time testing using one test pattern is finished, it is necessary to scan in the next test pattern and scan out the last test result. In this way, it is not possible to test the core circuit by consecutively applying serial test patterns.

When a core test circuit with parallel interfaces as described as an option in the above non-patent literature is used, the chip area required for the core test circuit and concomitant wiring and the number of terminals required for core testing increase. This makes the number of terminals included in an ordinary LSI tester inadequate for testing the core circuit.

A semiconductor integrated circuit according to an aspect of the present invention comprises: a core circuit having a plurality of input terminals and a plurality of output terminals; a combinational circuit having a plurality of input terminals and a plurality of output terminals; a scan path provided for the combinational circuit, the scan path being configured to input, in parallel, data scanned in through a plurality of cascaded scan flip-flops which are connected to the plurality of input terminals and output terminals of the combinational circuit to the plurality of input terminals of the combinational circuit and scan out data outputted, in parallel, from the plurality of output terminals of the combinational circuit; and a scan path sharing circuit which includes a plurality of first multiplexers respectively provided for the output terminals of the core circuit and each configured to selectively input either an output signal of the core circuit or a signal shifted in the scan path to one of the plurality of scan flip-flops and which is configured to scan out test results outputted from the plurality of output terminals of the core circuit by collecting the test results into corresponding ones of the plurality of scan flip-flops in parallel. In the semiconductor integrated circuit, the core circuit outside the combinational circuit can be tested using the scan path provided for the combinational circuit.

A core test circuit according to another aspect of the present invention is for testing a core circuit having a plurality of data input terminals and a plurality of data output terminals. The core test circuit comprises: a plurality of input shift registers for inputting test data which correspond to the plurality of data input terminals and which, when testing the core circuit, store n+1 (n being a positive integer) input test patterns to be applied to each of the data input terminals; and a plurality of output shift registers for outputting test data which correspond to the plurality of data output terminals and which, when testing the core circuit, store test results of n+1 test patterns outputted from each data output terminal. In the core test circuit: the plurality of input shift registers and the plurality of output shift registers are chain-connected such that test data can be scanned in and out through the chain-connected input and output shift registers; and, after n+1 patterns of test data are scanned in to each of the plurality of input shift registers, the n+1 patterns of test data are shifted through the input shift registers causing the n+1 patterns of test data to be applied from the input shift registers to the core circuit and test results of the n+1 patterns of test data are collected into the output shift registers by being shifted through the output shift registers to be eventually scanned out.

A core test circuit according to still another aspect of the present invention is for testing a core circuit having a plurality of data input terminals and a plurality of data output terminals. The core test circuit comprises: a BIST circuit for automatically generating at least n+1 test patterns (n being a positive integer) to be applied to each of the plurality of data input terminals; and a plurality of output shift registers for outputting test data which correspond to the plurality of data output terminals and which, when testing the core circuit, store test results of n+1 test patterns outputted from each of the plurality of data output terminals. In the core test circuit: the plurality of output shift registers are chain-connected to enable scanning out the test results and are configured such that, when testing the core circuit, n+1 test patterns generated by the BIST circuit are applied to the core circuit and such that test results of the n+1 test patterns are collected into the plurality of output shift registers by being shifted in the output shift registers to be eventually scanned out.

According to the semiconductor circuit of the present invention, scan flip-flops forming a scan path for a combinational circuit are used for core testing, so that the increase in the number of core elements required for core testing can be suppressed.

According to the core test circuit of the present invention, a shift register is provided for each data output terminal of a core circuit and the shift registers are chain-connected so as to scan out data. It is therefore possible to test the core circuit using consecutive test patterns without increasing the number of terminals required.

### BRIEF DESCRIPTION OF THE DRAWINGS

FIG. 1 is a block diagram of a semiconductor integrated circuit according to a first embodiment of the invention;

FIG. 2 is an enlarged block diagram of a portion of FIG. 1;

FIG. 3A is a diagram for describing different modes of core testing according to the first embodiment, representing scan shift mode (scan-in);

FIG. 3B is a diagram for describing different modes of core testing according to the first embodiment, representing core test mode;

FIG. 3C is a diagram for describing different modes of core testing according to the first embodiment, representing scan shift mode (scan-out);

FIG. 4A is an operation timing chart showing operation timing for scan testing of a combinational circuit according to the first embodiment;

FIG. 4B is an operation timing chart showing operation timing for core testing according to the first embodiment;

FIG. 5 is a block diagram of a core circuit and a test circuit for testing the core circuit according to a second embodiment of the invention;

FIG. 6 is a block diagram of a core circuit and a test circuit for testing the core circuit according to a third embodiment of the invention;

FIG. 7 is a block diagram of a core circuit and a test circuit for testing the core circuit according to a fourth embodiment of the invention;

FIG. 8 is a block diagram of a flip-flop circuit making up a scan path and a peripheral circuit around it according to a fifth embodiment of the invention; and

FIG. 9 is an overall block diagram of a test circuit (wrapper) based on IEEE 1500 Standard shown in FIG. 1 on page 12 of the above non-patent literature.

### DETAILED DESCRIPTION OF THE PREFERRED EMBODIMENTS

Embodiments of the present invention will be outlined below before going into their details. Note that the drawings referred to in the following description and the symbols used in such drawings only represent embodiment examples, and they do not limit variations of the embodiments of the present invention.

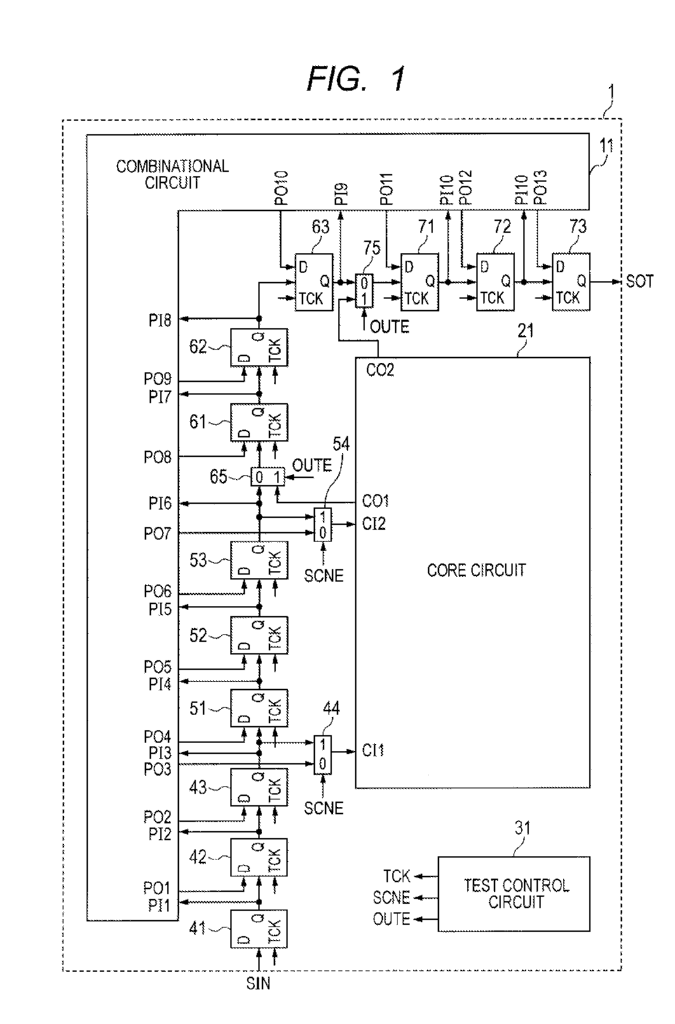

A semiconductor circuit 1 according to an embodiment of the present invention includes, as shown in FIG. 1, a core circuit 21, a combinational circuit 11, a scan path (41 to 43, 51 to 53, 61 to 63, 71 to 73) of the combinational circuit 11, and scan path sharing circuits (65, 75). The core circuit 21 has plural input terminals (CI1, CI2) and plural output terminals (CO1, CO2). The combinational circuit 11 has plural input terminals (PI1 to PI11) and plural output terminals (PO1 to PO13). The scan path (41 to 43, 51 to 53, 61 to 63, 71 to 73) of the combinational circuit 11 is configured by cascading the plural scan flip-flops (41 to 43, 51 to 53, 61 to 63, 71 to 73) connected to the plural input terminals (PI1 to PI11) and plural output terminals (PO1 to PO13) of the combinational circuit 11 such that data scanned in can be inputted in parallel to the plural input terminals (PI1 to PI11) of the combinational circuit 11 and such that the data outputted in parallel from the plural output terminals PO1 to PO13 of the combinational circuit can be scanned out. Namely, the plural scan flip-flops are cascaded such that the Q output of each scan flip-flop (41, for example) is cascaded to the data input terminal D of the next-stage scan flip-flop (42, for example). The scan path sharing circuits (65, 75) include plural first multiplexers (65, 75) provided for the output terminals (CO1, CO2), respectively, of the core circuit 21. The plural first multiplexers (65, 75) are configured such that they can each selectively input an output signal of the core circuit 21 or a signal shifted in the scan path (41 to 43, 51 to 53, 61 to 63, 71 to 73) to one of the plural scan flip-flops (41 to 43, 51 to 53, 61 to 63, 71 to 73). The scan path sharing circuits 65, 75 are configured such that they can scan out test results outputted from the plural output terminals (CO1, CO2) of the core circuit 21 to, out of the plural scan flip-flops (41 to 43, 51 to 53, 61 to 63, 71 to 73), the corresponding scan flip-flops in parallel. The above configuration makes it possible to test, using the scan path (41 to 43, 51 to 53, 61 to 63, 71 to 73) of the combinational circuit 11, the core circuit 21 not included in the combinational circuit 11.

The scan path sharing circuits (44, 54) may be further provided with plural second multiplexers (44, 54) which are provided for the input terminals (CI1, CI2), respectively, of the core circuit 21 and which selectively connect input signals (PO3, PO7) normally inputted to the input terminals (CI1, CI2) or output signals of plural scan flip-flops (Q outputs of the scan flip-flops 43, 53) to the corresponding input terminals (CI1, CI2), respectively. In this configuration, when testing the core circuit 21, data scanned in to the scan path can be inputted, in parallel, from the plural scan flip-flops (41 to 43, 51 to 53, 61 to 63, 71 to 73) to the plural input terminals (CI1, CI2) of the core circuit 21 via the plural second multiplexers (44, 54).

The circuit may be configured such that the plural first multiplexers (65, 75) are connected to as many scan flip-flops (61, 71) out of the cascaded scan flip-flops (41 to 43, 51-53, 61 to 63, 71 to 73), the scan flip-flops (61, 71) being mutually spaced apart with n flip-flops cascaded between them (n generally being a positive integer, which is two in the example shown in FIG. 1) and such that, when testing the core circuit 21, test results of ‘n+1’ consecutive patterns (i.e. three consecutive patterns in the example shown in FIG. 1) outputted in parallel from the plural output terminals (CO1, CO2) of the core circuit 21 are collected into the scan path (particularly, 1 to 63, 71 to 73) causing the test results to be shifted in the scan path (particularly, 1 to 63, 71 to 73) to be eventually scanned out (from an SOT terminal).

Also, the circuit may be configured such that the plural second multiplexers (44, 54) are connected to, out of the scan flip-flops (41 to 43, 51 to 53, 61 to 63, 71 to 73), the scan flip-flops (43, 53) with the output signals of the scan flip-flops of the preceding n stages (n being two in the example shown in FIG. 1, i.e. the output signals of the two scan flip-flops 41 and 42 preceding the scan flip-flop 43 and the output signals of the two scan flip-flops 51 and 52 preceding the scan flip-flop 53) connected to none of the first and the second multiplexers (65, 75, 44, 54), and such that, when testing the core circuit 21, the data scanned into the scan path (41 to 43, 51 to 53, 61 to 63, 71 to 73) is shifted by ‘n+1’ patterns (i.e. by three patterns in the example shown in FIG. 1) causing the ‘n+1’ consecutive patterns of data to be applied in parallel to the input terminals of the core circuit.

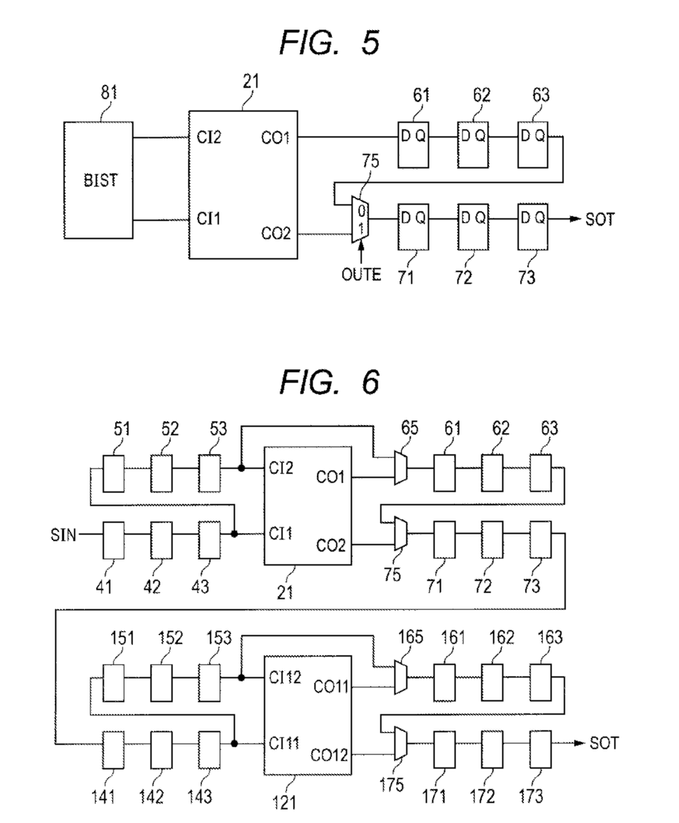

Furthermore, as shown in FIG. 5 as an example, the circuit may include a BIST circuit 81 for supplying input test data to the plural input terminals (CI1, CI2) of the core circuit 21 and may be configured such that the plural first multiplexers (65, 75) are connected to, out of the cascaded scan flip-flops (61 to 63, 71 to 73), as many scan flip-flops mutually spaced apart with n scan flip-flops disposed between them (n generally being a positive integer, which is two in the example shown in FIG. 1), such that, when testing the core circuit 21, ‘n+1’ patterns (i.e. three patterns in the example shown in FIG. 5) of test data are inputted in parallel from the BIST circuit 81 to the plural input terminals (CI1, CI2) of the core circuit 21 and such that test results of the ‘n+1’ consecutive patterns (i.e. three consecutive patterns in the example shown in FIG. 5) outputted in parallel from the plural output terminals (CO1, CO2) of the core circuit 21 are collected into the scan path (61 to 63, 71 to 73) causing them to be shifted in the scan path (1 to 63, 71 to 73) to be eventually scanned out (from the SOT terminal).

Still furthermore, the circuit may include, as shown in FIG. 6 as an example, plural core circuits (21, 121) and may be configured such that scan path sharing circuits (65, 75, 165, 175) are provided for the plural core circuits (21, 121) (the multiplexers, equivalent to 44, 54 in FIG. 1, on the input terminal (CI1, CI2, CI11, CI12) sides of the core circuits are omitted in FIG. 6) so as to enable the plural core circuits to be tested using the scan path of the combinational circuit 11.

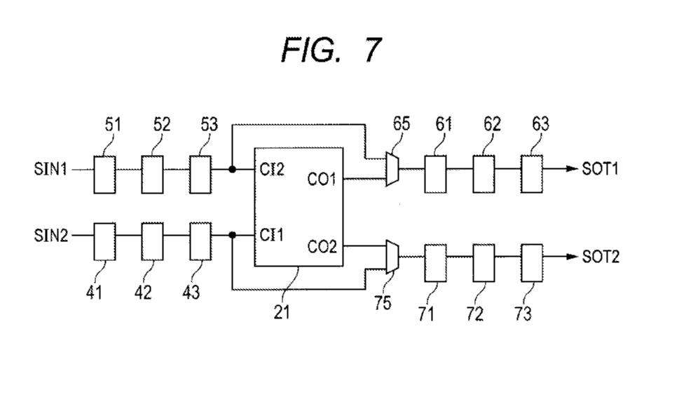

Still furthermore, the circuit may include, as shown in FIG. 7 as an example, plural scan paths (51 to 53, 61 to 63 and 41 to 43, 71 to 73) including scan-in terminals (SIN1, SIN2) and scan-out terminals (SOT1, SOT2), respectively, with the scan path sharing circuits configured to test the core circuit using the plural scan paths in parallel.

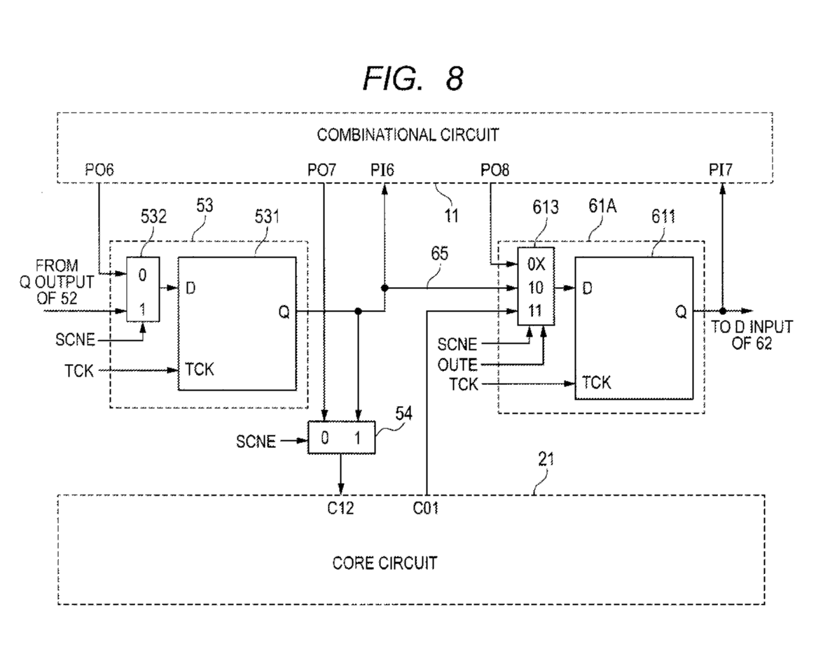

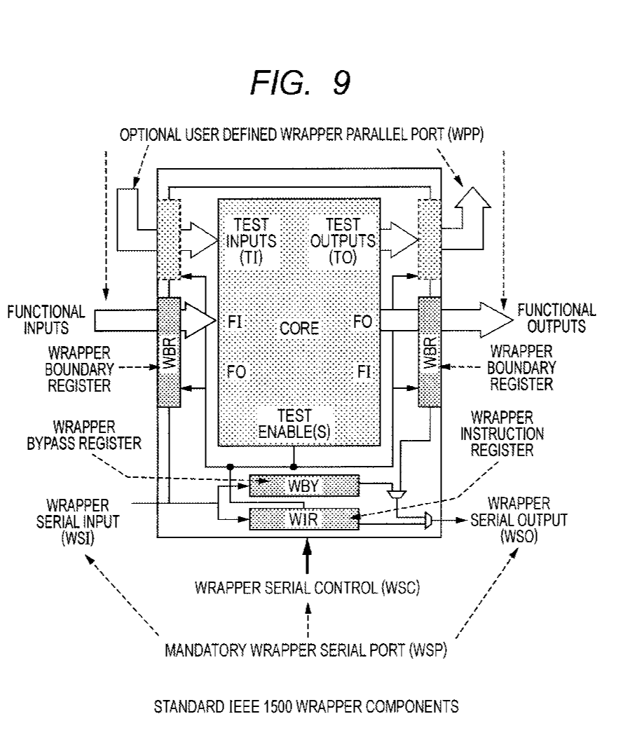

Still furthermore, the circuit may include, as shown in FIG. 8 as an example, a multiplexer scan flip-flop 61A in which the first multiplexer 613 and the flip-flop 611 are combined enabling the multiplexer scan flip-flop 61A to selectively collect and output, in synchronization with a clock signal TCK, an output signal of the preceding-stage scan flip-flop (Q output of flip-flop 531) or an output signal PO8 of the combinational circuit or an output signal CO1 of the core circuit.

The core test circuit according to an embodiment of the present invention is, as shown in FIG. 1 as an example, a core test circuit for testing the core circuit 21 and has plural data input terminals (CI1, CI2) and plural data output terminals (CO1, CO2). The core test circuit is provided with plural input shift registers (41 to 43 and 51 to 53) for inputting test data corresponding to the plural data input terminals (CI1, CI2) and plural output shift registers (61 to 63 and 71 to 73) for outputting test data corresponding to the plural data output terminals (CO1, CO2). When testing a core circuit, the plural input shift registers (41 to 43 and 51 to 53) store ‘n+1’ (n being a positive integer) test patterns to be applied to each of the data input terminals, and the plural output shift registers (61 to 63 and 71 to 73) store test results of ‘n+1’ patterns outputted from each of the data output terminals (CO1, CO2). The plural input shift registers (41 to 43 and 51 to 53) and plural output shift registers (61 to 63 and 71 to 73) are chain-connected to enable data to be scanned in and out. Namely, when testing a core circuit, first, ‘n+1’ test patterns are scanned in to each of the plural input shift registers (41 to 43 and 51 to 53). Next, the ‘n+1’ test patterns are applied from each of the input shift registers (41 to 43 and 51 to 53) to the core circuit 21 and test results of the ‘n+1’ test patterns are collected into each of the output shift registers (61 to 63 and 71 to 73) to eventually scan out the test results. This is done by shifting the test patterns through the input shift registers and the test results through the output shift registers (61 to 63 and 71 to 73).

The circuit may further include plural first multiplexers (65, 75) and plural second multiplexers (44, 54) and may be configured such that the plural first multiplexers (65, 75) are provided between the plural data output terminals (CO1, CO2) and the corresponding output shift registers (61 to 63 and 71 to 73), respectively, and selectively input either signals outputted from the plural data output terminals (CO1, CO2) or signals scanned in to be scanned out through the chain-connected input and output shift registers (i.e. signals inputted from the scan-in terminal SIN to be outputted from the scan-out terminal SOT) to the corresponding output shift registers. The plural second multiplexers (44, 54) are provided between the plural input shift registers (41 to 43 and 51 to 53) and the corresponding data input terminals (CI1, CI2) and selectively output either signals (PO3, PO7) to be inputted, during normal operation, to the corresponding data input terminals (CI1, CI2) or output signals (Q output of scan flip-flop 43 and Q output of scan flip-flop 53) of the corresponding input shift registers (41 to 43 and 51 to 53) to the corresponding data input terminals (CI1, CI2).

Furthermore, the plural input shift registers (41 to 43 and 51 to 53) for inputting test data and the plural output shift registers (61 to 63 and 71 to 73) for outputting test data may be parts of a scan path of a combinational circuit other than the core circuit 21.

The embodiments outlined above of the present invention will be described in detail below with reference to drawings.

### First Embodiment

FIG. 1 is a block diagram of a semiconductor integrated circuit according to a first embodiment of the present invention. Referring to FIG. 1, a semiconductor integrated circuit 1 includes a core circuit 21, a combinational circuit 11, and a circuit for testing the combinational circuit 11 and the core circuit 21. The core circuit 21 is a circuit with a fixed function and is normally configured as a hard macro with a fixed layout pattern. A typical core circuit may be a microprocessor, DSP, analog circuit, or memory, but it is not particularly defined.

The combinational circuit 11 is for incorporation in a so-called user logic the circuit configuration of which can be arbitrarily changed according to type and specifications. When designing a semiconductor integrator circuit having a desired function, design efficiency, design quality, and overall circuit performance can be improved by adopting, where possible, a core circuit already designed and verified as it is and designing a unique circuit required but not included in the core circuit as a user logic. A user logic includes a sequential circuit which includes, for example, flip-flops to operate in synchronization with clock pulses and a combinational circuit. To make user logic testing easier, the flip-flops are replaced by scan flip-flops and a test circuit capable of testing the combinational circuit using the scan path is included in the user logic. Such a scan path test circuit is included in the user logic, in many cases, automatically or semi-automatically using CAD. Scan flip-flops 41 to 43, 51 to 53, 61 to 63, and 71 to 73 shown in FIG. 1 are those which have replaced, to enable scan-path testing of the combinational circuit 11, flip-flops originally included in the user logic. There are also cases in which, to make up for flip-flops not provided but required for scan-path testing of the combinational circuit, scan flip-flops are added, to make testing easier, where no flip-flops are originally provided.

A test control circuit 31 is for controlling testing of the core circuit 21 and the combinational circuit 11. The test control circuit 31 may be, though not limited to, a test access port (TAP) controller for boundary scanning which complies with the Institute of Electrical and Electronics Engineers (IEEE) Standard 1149.

The scan path test circuit of the combinational circuit 11 includes the cascaded scan flip-flops 41 to 43, 51 to 53, 61 to 63, and 71 to 73 with the first scan flip-flop 41 connected to a scan-in terminal SIN and the last scan flip-flop 73 connected to a scan-out terminal SOT. Test patterns for testing the combinational circuit 11 are collected into the scan path circuit from the scan-in terminal SIN and are inputted to input terminals of the combinational circuit 11. Test results outputted from output terminals of the combinational circuit 11 are outputted to the scan path circuit to be then outputted, via the scan-out terminal SOT, to outside the semiconductor circuit 1.

The output signals of the scan flip-flops 41 to 43, 51 to 53, 61 to 63, and 71 to 73 are connected to the input terminals PI1 to PI11 of the combinational circuit 11, respectively. The output terminals PO1 to PO13 are each connected to the input terminal of a scan flip-flop among the scan flip-flops 41 to 43, 51 to 53, 61 to 63, and 71 to 73. Even though in FIG. 1, the output terminals PO3 and PO7 of the combinational circuit 11 are not connected to the input terminal of any scan flip-flop, for the purpose of testing the combinational circuit 11, it is desirable to connect them to scan flip-flops, too. Also, even though in FIG. 1, the scan flip-flops configuring the scan path of the combinational circuit 11 are shown disposed between the combinational circuit 11 and the core circuit 21, they are in reality disposed inside or in a peripheral portion of the combinational circuit 11.

The test control circuit 31 supply a shift clock signal TCK to the scan flip-flops 41 to 43, 51 to 53, 61 to 63, and 71 to 73 and outputs a scan enable signal SCNE that controls each of the scan flip-flops as to whether to have the data signal shifted from the preceding-stage scan flip-flop or input the signal outputted from the corresponding one of the output terminals PO1 to PO13.

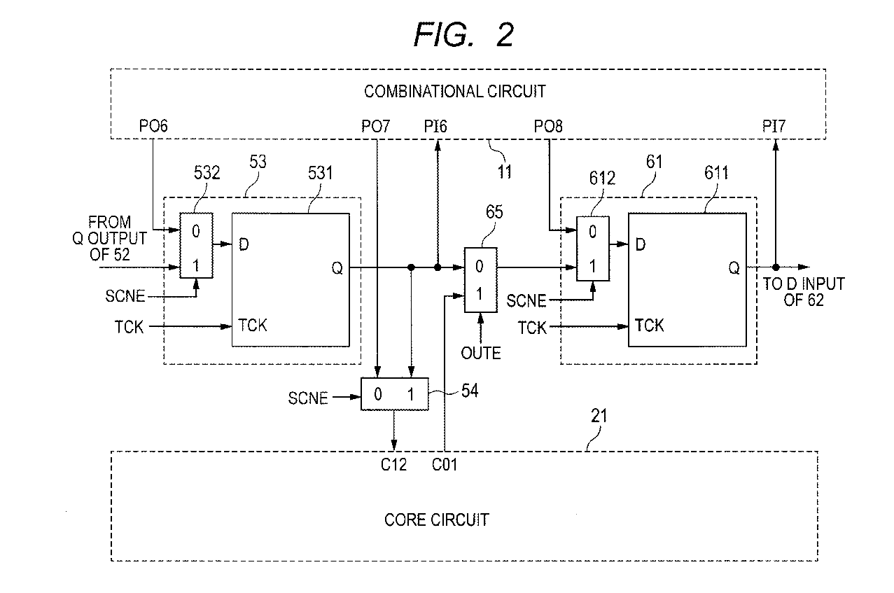

FIG. 2 is an enlarged block diagram of a circuit portion around the scan flip-flops 53 and 61 shown in FIG. 1. FIG. 2 includes parts, not shown in FIG. 1, of the configuration around the flip-flops 53 and 61. The scan flip-flop 53 includes a multiplexer 532 and a flip-flop 531. The scan flip-flop 61 includes a multiplexer 612 and a flip-flop 611. The multiplexers 532 and 612 are each connected with the scan enable signal SCNE signal that controls them. The multiplexer 532 is connected with, as input signals, the output terminal PO6 of the combinational circuit 11 and the Q output signal of the preceding-stage scan flip-flop 52. The multiplexer 612 is connected with, as input signals, the output terminal PO8 of the combinational circuit 11 and the Q output signal of the preceding-stage scan flip-flop 53. When the scan enable signal SCNE is at a low level (logical 0), the output terminals PO6 and PO8 of the combinational circuit are connected to the data input terminals D of the flip-flops 531 and 611. When the scan enable signal SCNE is at a high level (logical 1), the Q outputs of the corresponding preceding-stage scan flip-flops are connected to the data input terminals D of the flip-flops 531 and 611. The other scan flip-flops shown in FIG. 1 are also configured identically with the scan flip-flops 53 and 61 shown in FIG. 2. Namely, the scan enable signal SCNE is connected to each of the scan flip-flops shown in FIG. 1; when the scan enable signal SCNE is at a low level, each scan flip-flop inputs the signal outputted from the corresponding one of the output terminals PO1 to PO13 of the combinational circuit 11; and when the scan enable signal SCNE is at a high level, each scan flip-flop inputs, in synchronization with rising of the test clock signal TCK, the data signal outputted from the preceding-stage scan flip-flop and shifts the data to the next-stage scan flip-flop. When the combinational circuit is tested using the scan path, a core output enable signal OUTE which is outputted from the test control circuit 31 is fixed low.

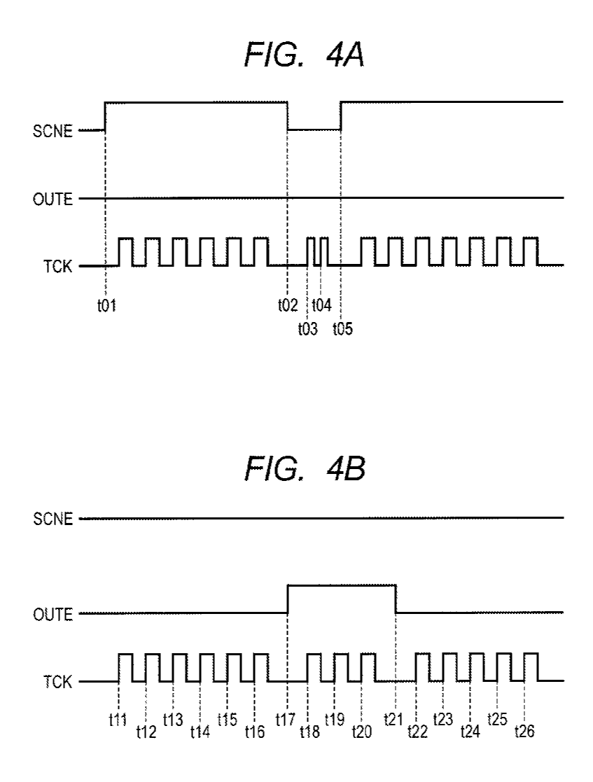

FIG. 4A is a timing chart of a scan test performed for the combinational circuit 11. First, at time t01, the scan enable signal SCNE is set high causing scan shift mode to be entered. When the scan shift mode is entered, the test patterns inputted, in synchronization with rising of the test clock signal TCK, from the scan-in terminal SIN are serially fed to the serially connected scan flip-flops. When the required test patterns have been set, the scan enable signal SCNE is set low at time t02, and the input connection of the multiplexer (for example, 532 or 612 shown in FIG. 2) inside each scan flip-flop is switched from the Q output of the preceding-stage scan flip-flop to the corresponding output terminal of the combinational circuit. The test patterns are applied, in synchronization with rising of the test clock signal TCK at time t03 to the input terminals PI1 to PI11 of the combinational circuit. Subsequently, the signals outputted from the output terminals PO1 to PO13 are inputted to the scan flip-flops 41 to 43, 51 to 53, 61 to 63, and 71 to 73 in synchronization with rising of the test clock signal TCK at time t04. Furthermore, at time t05, the scan enable signal SCNE is again set high causing the scan shift mode to be entered, and test results are scanned out, in synchronization with rising of the test clock signal TCK, to the scan-out terminal. As described above, a scan test can be performed for the combinational circuit by outputting the test clock signal TCK while appropriately switching the logical level of the scan enable signal SCNE. The scan test circuit of the combinational circuit and the scan test procedure described above are general examples, and they may be changed appropriately. The test clock signal TCK used at time t03 and time t04 may be replaced by a different clock signal. Also, input signal application from the scan flip-flops to the combinational circuit may be synchronized with an appropriate gate signal instead of synchronizing it with a rising edge of the test clock signal TCK.

According to the first embodiment, the scan path and scan flip-flops provided for use in testing the combinational circuit 11 are used to input test patterns to plural input terminals of the core circuit 21 in parallel and to collect test result signals outputted from plural output terminals of the core circuit 21. For this, the following circuits are further provided.

In the first embodiment, the first multiplexers 65 and 75 are provided for the plural output terminals CO1 and CO2 of the core circuit 21, respectively. The output terminals CO1 and CO2 are connected to the scan flip-flops 61 and 71 included in the scan path of the combinational circuit 11 via the first multiplexers 65 and 75. The input terminals of the first multiplexers 65 and 75 are connected with, in addition to the output terminals CO1 and CO2 of the core circuit 21, the data output signals Q from the preceding-stage scan flip-flops 53 and 63, respectively. The first multiplexers 65 and 75 send out, selectively according to the core output enable signal OUTE outputted from the test control circuit 31, either the signals outputted from the output terminals CO1 and CO2 of the core circuit or the data output signals Q outputted from the preceding-stage scan flip-flops 53 and 63 to the input terminals of the scan flip-flops 61 and 71. Namely, when the core output enable signal OUTE is low (logical 0), the data output signals Q from the preceding-stage scan flip-flops 53 and 63 are selected for input to the scan flip-flops 61 and 71 and, when the core output enable signal OUTE is high (logical 1), the signals from the output terminals CO1 and CO2 of the core circuit are selected for input to the scan flip-flops 61 and 71.

The input terminals CI1 and CI2 of the core circuit 21 are provided with second multiplexers 44 and 54, respectively. The second multiplexers 44 and 54 make switching to determine which to input to the input terminals CI1 and CI2 of the core circuit 21, the signals from the output terminals PO3 and PO7 of the combinational circuit 11 for normal operation other than testing or the output signals of the scan flip-flops 43 and 53 for testing the core circuit 21. Namely, when the scan enable signal SCNE outputted from the test control circuit 31 is low, the second multiplexers 44 and 54 connect the signals from the output terminals to the input terminals CI1 and CI2, respectively, for normal operation. When the scan enable signal SCNE outputted from the test control circuit 31 is high, the second multiplexers 44 and 54 connect the output signals from the scan flip-flops 43 and 53 to the input terminals CI1 and CI2 of the core circuit 21 for testing the core circuit 21. Even though in FIG. 1, the input terminals CI1 and CI2 of the core circuit 21 are shown connected, for normal operation, with the out terminals PO3 and PO7 of the combinational circuit 11, the signals to be inputted, during normal operation, to the input terminals CI1 and CI2 of the core circuit 21 need not necessarily be ones directly outputted from the combinational circuit 11. Arbitrarily selected signals may be inputted to the input terminals CI1 and CI2 of the core circuit 21.

As described above, with the first multiplexers 65 and 75 provided for the output terminals CO1 and CO2, respectively, and with the second multiplexers 44 and 54 provided for the input terminals CI1 and CI2, respectively, connecting the core circuit 21, via the first multiplexers 65 and 75 and the second multiplexers 44 and 54, to the scan flip-flops 61, 71, 43, and 53 included in the scan path of the combinational circuit 11 makes it possible to test the core circuit 21 using the scan path. Switching control for the first multiplexers 65 and 75 is performed according to the core output enable signal OUTE outputted from the test control circuit 31. For the second multiplexers 44 and 54, switching control can be performed making use of the scan enable signal SCNE used to control scan path switching for the combinational circuit.

In the first embodiment, the first multiplexers 65 and 75 are respectively connected to the scan flip-flops 61 and 71 with two scan flip-flops, i.e. the scan flip-flops 62 and 63, disposed between the scan flip-flops 61 and 71. This configuration allows test results of three consecutive patterns to be stored, before being scanned out, in the scan path of the combinational circuit.

The second multiplexers 44 and 54 are connected with the outputs of the scan flip-flops 43 and 53, respectively, with the two scan flip-flops 41 and 42 preceding the scan flip-flop 43 and two scan flip-flops 51 and 52 preceding the scan flip-flop 53 connected to none of the first and second multiplexers 65, 75, 44, and 54.

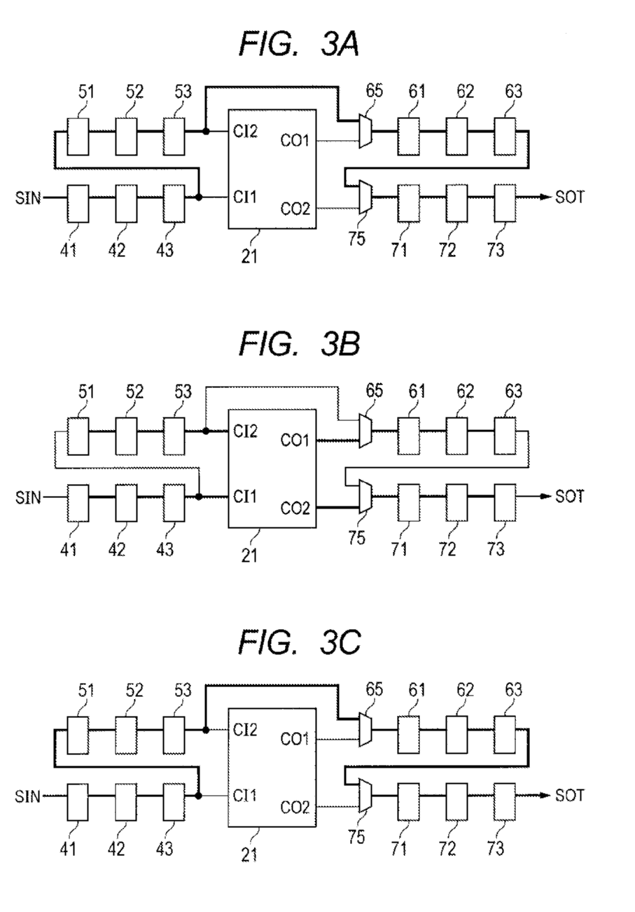

The reasons why the first multiplexers as well as the second multiplexers are connected to scan flip-flops which are spaced apart with other scan flip-flops cascaded between them, that is, why neither the first multiplexers nor the second multiplexers are connected to consecutive scan flip-flops will be explained by way of describing core testing operation. FIGS. 3A to 3C each show, out of the circuit configuration shown in FIG. 1, only the core circuit 21 and the scan flip-flops and multiplexers directly related with testing of the core circuit. For core testing, each of the input terminals of the core circuit 21 is connected with three serially connected scan flip-flops, and each of the output terminals of the core circuit 21 is connected, via a multiplexer, with three serially connected flip-flops. FIGS. 3A to 3C showing a same circuit portion correspond to different stages of a core test procedure with bold lines representing activated paths and thin lines representing paths not activated. FIG. 4B is a timing chart of core test operation.

With reference to FIG. 4B and FIGS. 3A to 3C, core testing operation will be described below. For core testing, the scan enable signal SCNE is fixed high causing the second multiplexers 44 and 54 and the multiplexers in the scan flip-flops to be fixed to select the output signals of the scan flip-flops. Hence, the second multiplexers 44 and 54 are omitted in FIGS. 3A to 3C.

Referring to FIG. 4B, test patterns scanned in from the scan-in terminal SIN in synchronization with rising of six pulses, at time t11 to time t16, of the test clock signal TCK are inputted to the scan flip-flops 41 to 43 and 51 to 53. In the circuit configuration shown in FIGS. 1 and 3A to 3C, the stages following the scan flip-flop 53 includes no scan flip-flop connected to an input terminal of the core circuit 21, so that, when a test pattern is inputted to the scan flip-flop 53, scanning in of test patterns is ended. Next, at time t17, the core output enable signal OUTE is set high causing the input connections of the first multiplexers 65 and 75 to be switched to the output terminal CO1 and CO2 of the core circuit 21, that is, their connections as shown in FIG. 3A are changed to the state as shown in FIG. 3B. At this time, three test patterns to be applied from the input terminal CI1 of the core circuit 21 are stored in the scan flip-flops 41 to 43. Similarly, three test patterns to be applied from the input terminal CI2 are stored in the scan flip-flops 51 to 53. At the rising edge of a test clock pulse at time 18, the respective first-pattern test results are inputted to the scan flip-flops 61 and 71. At the same time, the test patterns in the scan flip-flops are shifted to the respective next-stage scan flip-flops, namely, the test patterns in the scan flip-flops 43 and 53 are updated with the test patterns that have been in the scan flip-flops 42 and 52, respectively.

Next, at the rising edge at time t19 of the test clock signal TCK, the first-pattern test results stored at the scan flip-flops 61 and 71 are shifted to the scan flip-flops 62 and 72. At the same time, the respective second-pattern test results are inputted to the scan flip-flops 61 and 71, and the test patterns in the scan flip-flops 43 and 53 are updated with the respective third patterns that have been in the scan flip-flops 42 and 52.

Next, at the rising edge at time t20 of the test clock signal TCK, the second-pattern test results stored in the scan flip-flops 61 and 71 are shifted to the scan flip-flops 62 and 72. At the same time, the respective third-pattern test results are inputted to the scan flip-flops 61 and 71. As a result: the first-pattern test results are stored in the scan flip-flops 63 and 73; the second-pattern test results are stored in the scan flip-flops 62 and 72; and the third-pattern test results are stored in the scan flip-flops 61 and 71.

At time t21, the core output enable signal OUTE is set low causing the path connections of the multiplexers 65 and 75 to be changed from the state shown in FIG. 3B to the state shown in FIG. 3C. Subsequently, the test results are serially scanned out from the scan-out terminal SOT in synchronization with the rising edges at time t22 through time t26 of the test clock signal. The respective three-pattern test results can be observed as they are scanned out serially from the scan-out terminal SOT.

The core test circuit according to the first embodiment is provided with shift registers for inputting test data. The input shift registers can store ‘n+1’ test patterns (n being a positive integer) for the respective input terminals of the core circuit. The core test circuit is also provided with shift registers for outputting test data. The output shift registers can store ‘n+1’ test patterns (n being a positive integer) for the respective output terminals of the core circuit. The input shift registers and output shift registers are chain-connected. This makes it possible, without increasing the number of terminals for use in testing the core circuit, to consecutively apply ‘n+1’ test patterns to the respective input terminals of the core circuit and consecutively output the test results corresponding to the ‘n+1’ test patterns to the output shift registers. During the time the ‘n+1’ consecutive test patterns are used for testing, it is not necessary to scan in new test patterns from the scan-in terminal SIN or scan out test results obtained from the respective output terminals. The test results can be scanned out together later.

The number of scan flip-flops included, for use in testing a combinational circuit, in a large-scale semiconductor integrated circuit incorporating a user logic ranges from several tens of thousands to over several hundreds of thousands. The number of input and output terminals of a core circuit included in such a large-scale semiconductor integrated circuit, on the other hand, ranges merely from several tens to several thousands. Generally, a semiconductor integrated circuit includes much more scan flip-flops than the input and output terminals of a core circuit. It is therefore relatively easy to provide plural scan flip-flops for each of the input and output terminals of the core circuit by making shared use of the scan flip-flops provided in the vicinity of the core circuit. When it is not necessary to provide specialized flip-flops for use in core testing, the area overhead can be minimized.

As far as core testing is concerned, the first embodiment may be modified such that the scan path of the combinational circuit is not also used as input shift registers for inputting test data and output shift registers for outputting test data. Providing specialized shift registers only for inputting and outputting test data for use in core testing, however, increases the overhead of core testing. Therefore, in cases where shift registers or flip-flops which are not included in the scan path of the combinational circuit and which can be easily chain-connected are disposed around the core circuit, they may be made use of as the shift registers for inputting and outputting test data.

### Second Embodiment

FIG. 5 is a block diagram of a core circuit and a test circuit for testing the core circuit according to a second embodiment of the present invention. In FIG. 5, blocks approximately identical, as to configuration and operation, to those used in the first embodiment are denoted by the same symbols as those used in describing the first embodiment so as to avoid duplicate description. In the second embodiment, a built-in self-test (BIST) circuit is provided, instead of scan flip-flops, on the input terminal side of the core circuit. On the output terminal side of the core circuit, plural cascaded scan flip-flops (61 to 63 and 71 to 73) are provided for the respective output terminals as in the first embodiment. When, on the output terminal side of the core circuit, ‘n+1’ stages (n being a positive integer) of scan flip-flops are provided for each of the output terminals, the scan flip-flops can store test results of ‘n+1’ test patterns completely without causing them to be scanned out. Hence the BIST circuit is preferably capable of generating ‘n+1’ test patterns. Generally, when a BIST circuit is provided, test results are, after being compressed, outputted from the BIST circuit, or only judgments of test results are outputted from the BIST circuit. If, in such cases, a fault is detected, the fault cannot be easily analyzed. According to the second embodiment, however, even though the test patterns to be inputted to the core circuit 21 are generated in the BIST circuit, test results are neither compressed nor judged in the BIST circuit and they can be scanned out as they are from the SOT terminal. This makes fault analysis easy. As the BIST circuit, a general BIST circuit with a test pattern generator, for example, an SRAM BIST circuit or a logic BIST circuit can be used. To minimize the circuit area increase caused by forming a core test circuit, the scan flip-flops of the combinational circuit may be used also as the scan flip-flops (61 to 63 and 71 to 73) as in the first embodiment. It is also possible to make the scan flip-flops (61 to 63 and 71 to 73) usable also as flip-flops to perform different functions, or they may be provided as specialized scan flip-flops.

### Third Embodiment

FIG. 6 is a block diagram of core circuits and a test circuit for them according to a third embodiment of the present invention. The test circuit of the third embodiment is for testing plural core circuits 21 and 121. The plural core circuits 21 and 121 can be tested in parallel by chain-connecting the scan flip-flops (41 to 53, 51 to 53, 61 to 63, 71 to 73, 141 to 143, 151 to 153, 161 to 163, 171 to 173) provided for the input terminals (CI1, CI2, CI11, CI12) and output terminals (CO1, CO2, CO11, CO12) of the core circuit. With the scan flip-flops provided for the input and output terminals of the core circuit 21 and the scan flip-flops provided for the input and output terminals of the core circuit 121 chain-connected, all test patterns can be scanned in from the scan-in terminal SIN and all test results can be scanned out from the scan-out terminal SOT, so that the plural core circuits 21 and 121 can be tested without increasing the terminals for use in testing. Thus, it is possible to test the plural core circuits 21 and 121 in parallel using an existing LSI tester. In cases where the number of stages of scan flip-flops to be provided for each input terminal and each output terminal of each core circuit is set to ‘n+1’ (n being a positive integer), n is preferably common between the plural core circuits. In this way, the plural core circuits can be tested in parallel using, for each of the core circuits, ‘n+1’ consecutive patterns. The scan flip-flops (41 to 53, 51 to 53, 61 to 63, 71 to 73, 141 to 143, 151 to 153, 161 to 163, 171 to 173) may be specialized flip-flops. When other chain-connected flip-flops, for example, those included in the scan path of the combinational circuit can be used also as the scan flip-flops for core testing, the increase in the number of elements required for use in core testing can be minimized.

### Fourth Embodiment

FIG. 7 is a block diagram of a core circuit and a test circuit for testing the core circuit according to a fourth embodiment of the present invention. In the fourth embodiment, unlike in the first to the third embodiment in which the scan flip-flops provided for respective input terminals and output terminals are connected into a single scan chain, plural scan chains are provided and the core circuit 21 can be efficiently tested using the plural scan chains, namely by connecting each of the input terminals and output terminals of the core circuit to scan flip-flops included in one of the plural scan chains. When plural scan chains are provided, each scan chain can be shortened, so that the scan-in time and scan-out time taken during core testing can be reduced. On the other hand, however, it is necessary to increase the number of terminals of the LSI tester to be used. Therefore, when determining the number of scan chains to be provided for use in core testing, it is appropriate to take into consideration a trade-off between a reduction, which can be realized by increasing the number of scan chains, of scan-in time and scan-out time required for core testing and an increase, which will result from increasing the number of scan chains, in the number of terminals of the LSI tester. In the fourth embodiment, too, setting the number of serially connected scan flip-flops to be provided for each input terminal and each output terminal of the core circuit 21 to ‘n+1’ makes it possible to perform core testing using ‘n+1’ consecutive patterns without being interrupted by scan-in or scan-out operation. Also, the increase in the number of elements of the core test circuit can be minimized by making use of scan chains of other combinational circuits or existing flip-flops as the scan flip-flops (41 to 43, 51 to 53, 61 to 63, 71 to 73).

### Fifth Embodiment

FIG. 8 is a block diagram of a flip-flop circuit making up a scan path and a peripheral circuit around it according to a fifth embodiment of the present invention. In the fifth embodiment, scan flip-flops equivalent to modifications of the scan flip-flops 61 and 71 connected to the output terminals of the core circuit in the first embodiment are used. Referring to FIG. 2, in the first embodiment, the output terminal CO1 of the core circuit is connected to the scan flip-flop 61 via the first multiplexer 65. In the fifth embodiment, the function of the first multiplexer 65 of the first embodiment is incorporated in a multiplexer scan flip-flop 61A. Referring to FIG. 8, the multiplexer scan flip-flop 61A includes a multiplexer 613 and a flip-flop 611. The flip-flop 611 shown in FIG. 8 has the same function as the flip-flop 611 shown in FIG. 2. The multiplexer 613 connects, selectively according to two control signals, i.e. the scan enable signal SCNE and the core output enable signal OUTE, the signal outputted from the output terminal PO8 of the combinational circuit 11 or the signal shifted out from the preceding-stage scan flip-flop 531 or the signal outputted from the output terminal CO1 of the core circuit 21 to the data input terminal of the flip-flop 611. Namely: when the scan enable signal SCNE is low, the multiplexer 613 selects and outputs the signal outputted from the output terminal PO8 of the combinational circuit 11 regardless of the logical level of the core output enable signal OUTE; when the scan enable signal SCNE is high whereas the core output enable signal OUTE is low, the multiplexer 613 selects and outputs the signal shifted out from the preceding-stage scan flip-flop 531; and when both the scan enable signal SCNE and the core output enable signal OUTE are high, the multiplexer 613 selects and outputs the signal outputted from the output terminal CO1 of the core circuit 21. As far as the overall circuit functions are concerned, the fifth embodiment in which the multiplexer scan flip-flop 61A incorporating the function of the first multiplexer 65 shown in FIG. 2 is used does not differ from the first embodiment. Namely, the effects of the fifth embodiment are similar to the effects of the first embodiment.

Preferred embodiments of the present invention have been described above, but the invention is not limited to the preferred embodiments. Apparently, other variations and modifications can be easily made by those skilled in the art within the scope of the invention.

What is claimed is:

1. A semiconductor integrated circuit, comprising:
a core circuit having a plurality of input terminals and a plurality of output terminals;
a combinational circuit having a plurality of input terminals and a plurality of output terminals;
a scan path provided for the combinational circuit, the scan path being configured to input, in parallel, data scanned in through a plurality of cascaded scan flip-flops which are connected to the plurality of input terminals and output terminals of the combinational circuit to the plurality of input terminals of the combinational circuit and scan out data outputted, in parallel, from the plurality of output terminals of the combinational circuit; and
a scan path sharing circuit which includes a plurality of first multiplexers respectively provided for the output terminals of the core circuit and each configured to selectively input either an output signal of the core circuit or a signal shifted in the scan path to one of the plurality of scan flip-flops and which is configured to scan out test results outputted from the plurality of output terminals of the core circuit by collecting the test results into corresponding ones of the plurality of scan flip-flops in parallel;
wherein the core circuit outside the combinational circuit can be tested using the scan path provided for the combinational circuit.

2. The semiconductor integrated circuit according to claim 1,
wherein the scan path sharing circuit further includes a plurality of second multiplexers respectively provided for the plurality of input terminals of the core circuit and each configured to selectively input, to a corresponding one of the input terminals, either a signal to be inputted, during normal operation, to the corresponding one of the input terminals or a signal outputted from the plurality of scan flip-flops; and
wherein the scan path sharing circuit is configured such that, when testing the core circuit, the data scanned in to the scan path is inputted, in parallel, from the plurality of scan flip-flops to the plurality of input terminals of the core circuit via the plurality of second multiplexers.

3. The semiconductor integrated circuit according to claim 1, wherein the plurality of first multiplexers are connected to as many scan flip-flops among the cascaded scan flip-flops, the as many scan flip-flops mutually spaced apart with n scan flip-flops cascaded therebetween (n being a positive integer) and are configured such that, when testing the core circuit, test results of n+1 consecutive patterns outputted in parallel from the plurality of output terminals of the core circuit are inputted to the scan path in which the test results are shifted to be eventually scanned out.

4. The semiconductor integrated circuit according to claim 3, wherein the plurality of second multiplexers are each connected to one of the plurality of cascaded scan flip-flops with the output signals of n stages of scan flip-flops preceding the one of the plurality of cascaded scan flip-flops connected to none of the first and the second multiplexers and are configured such that, when testing the core circuit, the n+1 consecutive patterns of data scanned in to the scan path can be, by being shifted by n+1 patterns in the scan path, consecutively applied in parallel to the plurality of input terminals of the core circuit.

5. The semiconductor integrated circuit according to claim 1, further comprising a BIST circuit for supplying input test data to the plurality of input terminals of the core circuit,
wherein the plurality of first multiplexers are connected to as many scan flip-flops among the cascaded scan flip-flops, the as many scan flip-flops being mutually spaced apart with n scan flip-flops cascaded therebetween (n being a positive integer), and are configured such that, when testing the core circuit, n+1 consecutive patterns of test data are inputted in parallel from the BIST circuit to the plurality of input terminals of the core circuit and such that test results of n+1 consecutive patterns outputted in parallel from the plurality of output terminals of the core circuit are inputted to the scan path in which the test results are shifted to be eventually scanned out.

6. The semiconductor integrated circuit according to claim 1, further comprising:
at least one more core circuit,
wherein the scan path sharing circuit is provided for each of the plurality of core circuits and the plurality of core circuits can be tested using the scan path provided for the combinational circuit.

7. The semiconductor integrated circuit according to claim 1,
wherein the scan path includes a plurality of scan paths each having a scan-in terminal and a scan-out terminal; and
wherein the scan path sharing circuit is configured such that the core circuit can be tested using the plurality of scan paths in parallel.

8. The semiconductor integrated circuit according to claim 1, further comprising:
a multiplexer scan flip-flop in which the first multiplexer and the scan flip-flop are combined,
wherein the multiplexer scan flip-flop selectively collects and outputs, according to a clock signal, an output signal of a preceding-stage scan flip-flop or an output signal of the combinational circuit or an output signal of the core circuit.

9. A core test circuit for testing a core circuit having a plurality of data input terminals and a plurality of data output terminals, comprising:
a plurality of input shift registers for inputting test data which correspond to the plurality of data input terminals and which, when testing the core circuit, store n+1 (n being a positive integer) input test patterns to be applied to each of the data input terminals; and
a plurality of output shift registers for outputting test data which correspond to the plurality of data output terminals and which, when testing the core circuit, store test results of n+1 test patterns outputted from each data output terminal,
wherein the plurality of input shift registers and the plurality of output shift registers are chain-connected such that test data can be scanned in and out through the chain-connected input and output shift registers, and
wherein, after n+1 patterns of test data are scanned in to each of the plurality of input shift registers, the n+1 patterns of test data are shifted through the input shift registers causing the n+1 patterns of test data to be applied from the input shift registers to the core circuit and test results of the n+1 patterns of test data are collected into the output shift registers by being shifted through the output shift registers to be eventually scanned out.

10. The core test circuit according to claim 9, further comprising:
a plurality of first multiplexers which are disposed between the plurality of data output terminals and the corresponding output shift registers and which selectively input either signals outputted from the plurality of data output terminals or signals scanned in to a chain-connected path to be eventually scanned out to the corresponding output shift registers; and
a plurality of second multiplexers which are disposed between the plurality of input shift registers and the corresponding data input terminals and which selectively output either signals to be inputted, during normal operation, to the corresponding data input terminals or signals outputted from the corresponding input shift registers to the corresponding data input terminals.

11. The core test circuit according to claim 9, wherein the plurality of input shift registers and the plurality of output shift registers are parts of a scan path for a combinational circuit other than the core circuit.

12. A core test circuit for testing a core circuit having a plurality of data input terminals and a plurality of data output terminals, comprising:
a BIST circuit for automatically generating at least n+1 test patterns (n being a positive integer) to be applied to each of the plurality of data input terminals; and
a plurality of output shift registers for outputting test data which correspond to the plurality of data output terminals and which, when testing the core circuit, store test results of n+1 test patterns outputted from each of the plurality of data output terminals,
wherein the plurality of output shift registers are chain-connected to enable scanning out the test results and are configured such that, when testing the core circuit, n+1 test patterns generated by the BIST circuit are applied to the core circuit and such that test results of the n+1 test patterns are collected into the plurality of output shift registers by being shifted in the output shift registers to be eventually scanned out.
